(19) United States
(12) Patent Application Publication
(10) Pub. No.: US 2023/0247758 A1
(43) Pub. Date: Aug. 3, 2023

(54) PRINTED CIRCUIT BOARD, METHOD, AND SYSTEM

(71) Applicants: Navin Sakthivel, Spring, TX (US); Aaron Avagliano, Tomball, TX (US); Dinesh Kommireddy, Houston, TX (US); Marc Stephen Ramirez, Missouri City, TX (US)

(72) Inventors: Navin Sakthivel, Spring, TX (US); Aaron Avagliano, Tomball, TX (US); Dinesh Kommireddy, Houston, TX (US); Marc Stephen Ramirez, Missouri City, TX (US)

(73) Assignee: Baker Hughes Oilfield Operations LLC, Houston, TX (US)

(21) Appl. No.: 17/588,635

(22) Filed: Jan. 31, 2022

(51) Int. Cl. H05K 1/02; H05K 3/00; H05K 3/46; E21B 47/01

(52) U.S. Cl. CPC H05K 1/024; H05K 3/0044; H05K 3/4644; E21B 47/01; H05K 2201/10098; H05K 2201/09018; H05K 2203/107; B33Y 80/00

(57) ABSTRACT

A printed circuit board (PCB) including a rigid dielectric layer having a curved geometry, and a conductive layer attached to the dielectric layer. A method for making a printed circuit board (PCB) including depositing a layer of dielectric material onto a surface, curing and sintering the material on the surface, depositing a first layer of conductive material on the layer of dielectric material, and depositing a second layer of conductive material on the first layer of conductive material, the second layer being thinner in cross section than the first layer. A system for producing a curved rigid PCB including a housing, a build platform disposed in the housing, a mobile robotic depositor disposed upon the build platform, and a print head disposed in the housing and in printing proximity to the build platform, the head having a plurality of deposition nozzles and a laser.

### BACKGROUND

Printed circuit boards (PCB) are ubiquitously used in industry. Such boards are planar and rigid or are flexible. There are also instances of rigid planar boards that are connected to other rigid boards by flexible sections. While these PCBs are widely used and reliable, they also require securement, especially when employing flexible sections or entirely flexible boards. Securements potentially increase maintenance and hence can be undesirable. The arts always favorably receive innovation that improves reliability and convenience.

### SUMMARY

An embodiment of a printed circuit board (PCB) including a rigid dielectric layer having a curved geometry, and a conductive layer attached to the dielectric layer.

An embodiment of a method for making a printed circuit board (PCB) including depositing a layer of dielectric material onto a surface, curing and sintering the material on the surface, depositing a first layer of conductive material on the layer of dielectric material, and depositing a second layer of conductive material on the first layer of conductive material, the second layer being thinner in cross section than the first layer.

An embodiment of a system for producing a curved rigid PCB including a housing, a build platform disposed in the housing, a mobile robotic depositor disposed upon the build platform, and a print head disposed in the housing and in printing proximity to the build platform, the head having a plurality of deposition nozzles and a laser.

An embodiment of a borehole system including a borehole in a subsurface formation, a string disposed in the borehole, and a printed circuit board disposed within or as a part of the string.

### BRIEF DESCRIPTION OF THE DRAWINGS

The following descriptions should not be considered limiting in any way. With reference to the accompanying drawings, like elements are numbered alike:

FIG. 1 is a schematic view of a rigid curved PCB disposed upon a wellbore tubular;

FIG. 2 is a flow chart defining a method for building a rigid curved PCB;

FIG. 3 is a schematic view of a system to build the rigid curved PCB; and

FIG. 4 is a view of a borehole system including the rigid curved disclosed herein.

### DETAILED DESCRIPTION

A detailed description of one or more embodiments of the disclosed apparatus and method are presented herein by way of exemplification and not limitation with reference to the Figures.

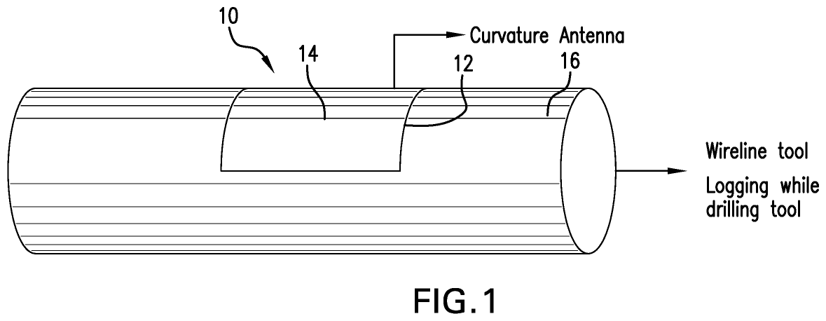

Referring to FIG. 1, a printed circuit board (PCB) 10 comprises a rigid dielectric layer 12 having a curved geometry and a conductive layer 14 attached to the dielectric layer 12. In an embodiment, the curvature is selected to nest with a tubular structure 16 upon which the PCB 10 is to be mounted. In embodiments, this structure 16 is a downhole tool or part of a string used in a borehole for hydrocarbon exploration and production or fluid sequestration. In embodiments, the PCB 10 is configured as an antenna. RF and NMR antennae are widely used in industry including the downhole industry.

The rigid PCB 10 that is already in a curved geometry improves functionality since it will easily attach to a target tubular 16 and may be of several layers in thickness, if desired, without drawbacks of flexible PCBs with regard to thickness and failure associated with bending thicker (greater layer numbers) flexible PCBs as well as having a greater Q factor (Q=ωL/R, where ω is the angular frequency in unit radians/second, L is the inductance in Henry, and R is the resistance in Ohms) than a flexible antenna. Antennae of the prior art employing flexible dielectric layers and then formed around the tubular 16 and attached thereto using tape, etc., limits functionality and robustness. Prior to the present disclosure however, rigid curved PCBs were not known to the industry.

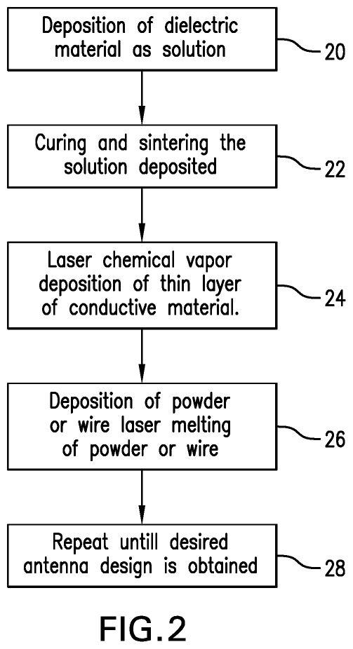

Referring to FIG. 2, a flow chart is presented that enables the construction of a rigid pre-curved PCB as described above. In particular, a method including 5 steps that may then be repeated an unlimited number of times to build layers of dielectric material and conductive material is detailed. Step 1. represented by box 20 is to deposit onto a build surface a dielectric material. The dielectric material may be powdered or in solution form having a binder therein that is removable in a subsequent step. The deposition may occur in an additive manufacturing process. Once the material is deposited, for example by a nozzle of the additive manufacturing process, the deposited dielectric material is cured and, in some embodiments, sintered. This occurs in step 2 represented by box 22 with the application of heat and or laser radiation to cure and sinter the material into a rigid and curved dielectric base ready for the application of conductive material thereto. In step 3, represented by box 24, a think layer of conductive material is applied. By “thin” it is meant 0.1 mil. This step is performed in an embodiment using a laser vapor chemical deposition (LCVD) process. Step 4 represented by box 26, deposits additional conductive material atop the conductive material deposited in step 3. The step 4 material may be applied more thickly as desired, “thick” meaning 20 mil as used herein. The step 4 deposition may be by powder or wire deposition and then laser melting of the powder or wire to bond with the LCVD deposited think metal of step 3. Step 3 is particularly important in the process disclosed since while one might believe that step 4 could follow directly from step 2, if this were attempted, thermal stresses, cracks, CTE mismatch, distortions, etc. would be the likely result. Where step 3 is performed however, better adhesion and avoidance of all of these drawbacks is achieved. Finally, as represented in box 28 as step 5, it is to be appreciated that the four-step method outlined above may be repeated until a completed PCB is produced that is rigid and curved and with a particular function, such as, for example, an antenna.

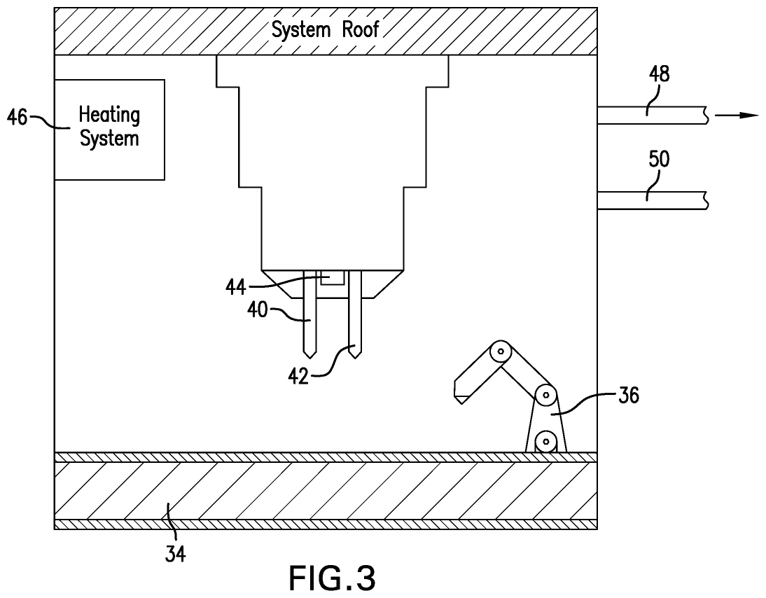

The method discussed above may be advantageously carried out in an additive manufacturing system 30, referring to FIG. 3. System 30 includes a housing 32 in Which a build platform 34 is disposed. The build platform 34 supports a robotic arm 36 that includes componentry to enable the LCVD of step 3. The arm is commercially available from Physik Instrumente. The system 30 also includes a deposition head 38 having at least a first nozzle 40 and a second nozzle 42 configured to deposit different materials. In one embodiment nozzle 40 deposits dielectric material and nozzle 42 deposits conductive material. Head 38 further includes a laser 44 for curing, sintering and melting as appropriate. Suitable heads are available from Kuka robotics. The system 30 also includes a heater 46 to control atmospheric temperature within the system 30 and also a gas inlet 48 and gas outlet 50 to control atmospheric chemical makeup within the system 30. Each of the steps of the method set forth in FIG. 3 may be advantageously carried out in the single system 30.

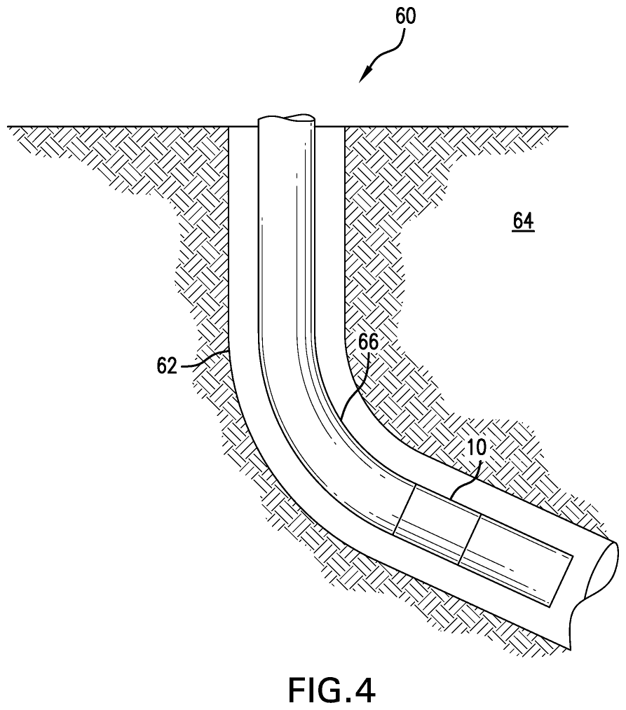

Referring to FIG. 4, a borehole system 60 is illustrated. The system 60 includes a borehole 62 in a subsurface formation 64. A string 66 is disposed in the borehole 62. A PCB 10 is disposed within or as a part of the string 66.

Set forth below are some embodiments of the foregoing disclosure:

Embodiment 1: A printed circuit board (PCB) including a rigid dielectric layer having a curved geometry, and a conductive layer attached to the dielectric layer.

Embodiment 2: The PCB as in any prior embodiment further comprising another rigid dielectric layer sandwiching the conductive layer.

Embodiment 3: The PCB as in any prior embodiment further comprising another conductive layer attached to the another rigid dielectric layer.

Embodiment 4: The PCB as in any prior embodiment wherein the conductive layer includes a trace having a cross section that differs in different segments of the trace.

Embodiment 5: The PCB as in any prior embodiment wherein a multiplicity of the rigid layer and the conductive layer are disposed in a stack.

Embodiment 6: The PCB as in any prior embodiment wherein the PCB forms at least a part of an antenna.

Embodiment 7: A method for making a printed circuit board (PCB) including depositing a layer of dielectric material onto a surface, curing and sintering the material on the surface, depositing a first layer of conductive material on the layer of dielectric material, and depositing a second layer of conductive material on the first layer of conductive material, the second layer being thinner in cross section than the first layer.

Embodiment 8: The method as in any prior embodiment wherein the dielectric material is deposited as a powder or a solution.

Embodiment 9: The method as in any prior embodiment wherein the powder of solution is deposited by a nozzle of an additive manufacturing system.

Embodiment 10: The method as in any prior embodiment wherein the curing and sintering is by laser.

Embodiment 11: The method as in any prior embodiment wherein the depositing of the first layer of conductive material is by laser chemical vapor deposition.

Embodiment 12: The method as in any prior embodiment wherein the second layer of conductive material is deposited by a nozzle of an additive manufacturing system.

Embodiment 13: The method as in any prior embodiment wherein the second layer of conductive material is deposited as a powder or a wire.

Embodiment 14: The method as in any prior embodiment wherein the second layer of conductive material is melted by laser.

Embodiment 15: The method as in any prior embodiment wherein each element is repeated seriatim until a completed rigid curved PCB is constructed having predetermined electrical attributes.

Embodiment 16: The method as in any prior embodiment wherein the PCB forms an antenna.

Embodiment 17: A system for producing a curved rigid PCB including a housing, a build platform disposed in the housing, a mobile robotic depositor disposed upon the build platform, and a print head disposed in the housing and in printing proximity to the build platform, the head having a plurality of deposition nozzles and a laser.

Embodiment 18: The system as in any prior embodiment wherein a first of the plurality of deposition nozzles is configured to deposit a dielectric material or solution on the build platform and a second of the plurality of deposition nozzles is configured to deposit a powder or wire onto a layer of conductive material that is already deposited via laser chemical vapor deposition upon the dielectric material.

Embodiment 19: The system as in any prior embodiment wherein the depositor is configured for laser chemical vapor deposition.

Embodiment 20: The system as in any prior embodiment further including a system atmosphere inlet connected to the housing, a system atmosphere outlet connected to the housing, a heating system operably connected to the housing to manipulate temperature within the housing.

Embodiment 21: A borehole system including a borehole in a subsurface formation, a string disposed in the borehole, and a printed circuit board as in any prior embodiment disposed within or as a part of the string.

Embodiment 22: The borehole system as in any prior embodiment wherein the PCB forms at least a part of an antenna.

The use of the terms “a” and “an” and “the” and similar referents in the context of describing the invention (especially in the context of the following claims) are to be construed to cover both the singular and the plural, unless otherwise indicated herein or clearly contradicted by context. Further, it should be noted that the terms “first,” “second,” and the like herein do not denote any order, quantity, or importance, but rather are used to distinguish one element from another. The terms “about”, “substantially” and “generally” are intended to include the degree of error associated with measurement of the particular quantity based upon the equipment available at the time of filing the application. For example, “about” and/or “substantially” and/or “generally” can include a range of ±8% or 5%, or 2% of a given value.

The teachings of the present disclosure may be used in a variety of well operations. These operations may involve using one or more treatment agents to treat a formation, the fluids resident in a formation, a borehole, and/or equipment in the borehole, such as production tubing. The treatment agents may be in the form of liquids, gases, solids, semi-solids, and mixtures thereof. Illustrative treatment agents include, but are not limited to, fracturing fluids, acids, steam, water, brine, anti-corrosion agents, cement, permeability modifiers, drilling muds, emulsifiers, demulsifiers, tracers, flow improvers etc. Illustrative well operations include, but are not limited to, hydraulic fracturing, stimulation, tracer injection, cleaning, acidizing, steam injection, water flooding, cementing, etc.

While the invention has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited.

What is claimed is:

1. A printed circuit board (PCB) comprising:
a rigid dielectric layer having a curved geometry; and
a conductive layer attached to the dielectric layer.

2. The PCB as claimed in claim 1 further comprising another rigid dielectric layer sandwiching the conductive layer.

3. The PCB as claimed in claim 2 further comprising another conductive layer attached to the another rigid dielectric layer.

4. The PCB as claimed in claim 1 wherein the conductive layer includes a trace having a cross section that differs in different segments of the trace.

5. The PCB as claimed in claim 1 wherein a multiplicity of the rigid layer and the conductive layer are disposed in a stack.

6. The PCB as claimed in claim 1 wherein the PCB forms at least a part of an antenna.

7. A method for making a printed circuit board (PCB) comprising:
depositing a layer of dielectric material onto a surface;
curing and sintering the material on the surface;
depositing a first layer of conductive material on the layer of dielectric material; and
depositing a second layer of conductive material on the first layer of conductive material, the second layer being thinner in cross section than the first layer.

8. The method as claimed in claim 7 wherein the dielectric material is deposited as a powder or a solution.

9. The method as claimed in claim 8 wherein the powder of solution is deposited by a nozzle of an additive manufacturing system.

10. The method as claimed in claim 7 wherein the curing and sintering is by laser.

11. The method as claimed in claim 7 wherein the depositing of the first layer of conductive material is by laser chemical vapor deposition.

12. The method as claimed in claim 7 wherein the second layer of conductive material is deposited by a nozzle of an additive manufacturing system.

13. The method as claimed in claim 7 wherein the second layer of conductive material is deposited as a powder or a wire.

14. The method as claimed in claim 7 wherein the second layer of conductive material is melted by laser.

15. The method as claimed in claim 7 wherein each element is repeated seriatim until a completed rigid curved PCB is constructed having predetermined electrical attributes.

16. The method as claimed in claim 7 wherein the PCB forms an antenna.

17. A system for producing a curved rigid PCB comprising:
a housing;
a build platform disposed in the housing;
a mobile robotic depositor disposed upon the build platform; and
a print head disposed in the housing and in printing proximity to the build platform, the head having a plurality of deposition nozzles and a laser.

18. The system as claimed in claim 17 wherein a first of the plurality of deposition nozzles is configured to deposit a dielectric material or solution on the build platform and a second of the plurality of deposition nozzles is configured to deposit a powder or wire onto a layer of conductive material that is already deposited via laser chemical vapor deposition upon the dielectric material.

19. The system as claimed in claim 17 wherein the depositor is configured for laser chemical vapor deposition.

20. The system as claimed in claim 17 further including:
a system atmosphere inlet connected to the housing;
a system atmosphere outlet connected to the housing;
a heating system operably connected to the housing to manipulate temperature within the housing.

21. A borehole system comprising:
a borehole in a subsurface formation;
a string disposed in the borehole; and
a printed circuit board as claimed in claim 1 disposed within or as a part of the string.

22. The borehole system as claimed in claim 21 wherein the PCB forms at least a part of an antenna.
